(19) United States
(12) Patent Application Publication
(10) Pub. No.: US 2025/0359366 A1
(43) Pub. Date: Nov. 20, 2025

(54) PHOTODETECTION DEVICE AND ELECTRONIC DEVICE

(71) Applicant: SONY SEMICONDUCTOR SOLUTIONS CORPORATION, KANAGAWA (JP)

(72) Inventor: ATSUSHI MASAGAKI, KANAGAWA (JP)

(21) Appl. No.: 18/854,891

(22) PCT Filed: Mar. 6, 2023
(86) PCT No.: PCT/JP2023/008207

§ 371 Date: Oct. 7, 2024

(30) Foreign Application Priority Data
Apr. 15, 2022 (JP) 2022-067462

(51) Int. Cl. H10F 39/00; H10F 39/18

(52) U.S. Cl. CPC H10F 39/80373; H10F 39/18

(57) ABSTRACT

A photodetection device is provided capable of increasing an amount of charge that can be accumulated in a photoelectric conversion portion. The semiconductor device includes: a semiconductor substrate; the photoelectric conversion portion that is formed on the semiconductor substrate and generates and accumulates a charge according to an amount of received light; a charge holding portion that holds the charge generated by the photoelectric conversion portion; and a transfer gate that transfers the charge accumulated by the photoelectric conversion portion to the charge holding portion. Then, the photoelectric conversion portion has a configuration including a p-type semiconductor region containing an impurity of p-type and formed continuously in a thickness direction of the semiconductor substrate, and an n-type semiconductor region containing an impurity of n-type and formed in a region in contact with the p-type semiconductor region and formed continuously in the thickness direction of the semiconductor substrate. Here, the n-type semiconductor region has a constant impurity concentration of the impurity of n-type in the thickness direction of the semiconductor substrate. Furthermore, the transfer gate has a configuration including a vertical gate electrode extending from a front surface of the semiconductor substrate to a depth deeper than that of an end portion of the n-type semiconductor region located on a back surface side of the semiconductor substrate.

### TECHNICAL FIELD

The present technology (technology according to the present disclosure) relates to a photodetection device and an electronic device.

### BACKGROUND ART

Conventionally, for example, there has been proposed a photodetection device including: a semiconductor substrate; a photoelectric conversion portion formed on the semiconductor substrate and generating and accumulating a charge according to an amount of received light; a floating diffusion (hereinafter, also referred to as “FD”) formed on a side of a surface (hereinafter, also referred to as a “front surface”) on an opposite side from a light incident surface of the semiconductor substrate; and a transfer gate formed on the front surface side of the semiconductor substrate and transferring the charge accumulated in the photoelectric conversion portion to the FD (See, for example, Patent Document 1).

### CITATION LIST

### Patent Document

Patent Document 1: Japanese Patent Application Laid-Open No. 2018-148116

### SUMMARY OF THE INVENTION

### Problems to be Solved by the Invention

In order to implement the photodetection device described in Patent Document 1, it is necessary to form a potential gradient in which potential becomes deeper from the light incident surface side toward the front surface side in the photoelectric conversion portion so that the charge accumulated on the light incident surface side of the photoelectric conversion portion moves to the transfer gate side (front surface side) at the time of transfer of the charge to the FD. However, in a case where such a potential gradient is formed, a depth of potential on the light incident surface side of the photoelectric conversion portion becomes shallower than a depth of potential on the front surface side. For that reason, there has been a possibility that an amount of charge (saturated amount of charge Qs) that can be accumulated as the entire photoelectric conversion portion decreases.

An object of the present disclosure is to provide a photodetection device and an electronic device capable of increasing an amount of charge that can be accumulated in a photoelectric conversion portion.

### Solutions to Problems

A gist is that a photodetection device of the present disclosure includes: (a) a semiconductor substrate; (b) a photoelectric conversion portion that is formed on the semiconductor substrate and generates and accumulates a charge according to an amount of received light; (c) a charge holding portion that holds the charge generated by the photoelectric conversion portion; and (d) a transfer gate that transfers the charge accumulated by the photoelectric conversion portion to the charge holding portion, in which (e) the photoelectric conversion portion includes a p-type semiconductor region containing an impurity of p-type and formed continuously in a thickness direction of the semiconductor substrate, and (f) an n-type semiconductor region containing an impurity of n-type and formed in a region in contact with the p-type semiconductor region and formed continuously in the thickness direction of the semiconductor substrate, (g) the n-type semiconductor region has a constant impurity concentration in the thickness direction of the semiconductor substrate, and (h) the transfer gate includes a vertical gate electrode extending from a first surface that is a surface of two surfaces of the semiconductor substrate and closer to the charge holding portion to a depth deeper than that of an end portion of the n-type semiconductor region located on a side of a second surface that is a surface on an opposite side from the first surface.

A gist is that an electronic device of the present disclosure includes a photodetection device including: (a) a semiconductor substrate; (b) a photoelectric conversion portion that is formed on the semiconductor substrate and generates and accumulates a charge according to an amount of received light; (c) a charge holding portion that holds the charge generated by the photoelectric conversion portion; and (d) a transfer gate that transfers the charge accumulated by the photoelectric conversion portion to the charge holding portion, in which (e) the photoelectric conversion portion includes a p-type semiconductor region containing an impurity of p-type and formed continuously in a thickness direction of the semiconductor substrate, and (f) an n-type semiconductor region containing an impurity of n-type and formed in a region in contact with the p-type semiconductor region and formed continuously in the thickness direction of the semiconductor substrate, (g) the n-type semiconductor region has a constant impurity concentration in the thickness direction of the semiconductor substrate, and (h) the transfer gate includes a vertical gate electrode extending from a first surface that is a surface of two surfaces of the semiconductor substrate and closer to the charge holding portion to a depth deeper than that of an end portion of the n-type semiconductor region located on a side of a second surface that is a surface on an opposite side from the first surface.

### BRIEF DESCRIPTION OF DRAWINGS

FIG. 1 is a diagram illustrating an overall configuration of a solid-state imaging device according to a first embodiment.

FIG. 2 is a diagram illustrating a cross-sectional configuration of the solid-state imaging device in the case of being cut along a line A-A′ in FIG. 1.

FIG. 3 is a diagram illustrating a cross-sectional configuration of the solid-state imaging device in the case of being cut along a line B-B′ in FIG. 2.

FIG. 4 is a diagram illustrating a potential distribution in a photoelectric conversion portion.

FIG. 5 is a diagram illustrating a potential at a position of a line C-C′ in FIG. 4.

FIG. 6 is a diagram illustrating a potential at a position of a line D-D′ in FIG. 4.

FIG. 7 is a diagram illustrating a potential distribution in the photoelectric conversion portion.

FIG. 8 is a diagram illustrating a potential at a position of a line E-E′ in FIG. 7.

FIG. 9 is a diagram illustrating a potential distribution in the photoelectric conversion portion.

FIG. 10 is a diagram illustrating a potential at a position of a line F-F′ in FIG. 9.

FIG. 11 is a diagram illustrating a potential at a position of a line G-G′ in FIG. 9.

FIG. 12 is a diagram illustrating a cross-sectional configuration of the solid-state imaging device according to a second embodiment.

FIG. 13 is a diagram illustrating a cross-sectional configuration of the solid-state imaging device in the case of being cut along a line H-H′ in FIG. 12.

FIG. 14 is a potential distribution in a case where a potential of a buried electrode is in a LOW state.

FIG. 15 is a potential distribution in a case where the potential of the buried electrode is in a HIGH state.

FIG. 16 is a diagram illustrating a potential in the case of being viewed from a thickness direction of a semiconductor substrate.

FIG. 17 is a diagram illustrating a cross-sectional configuration of the solid-state imaging device according to a modification.

FIG. 18 is a diagram illustrating a cross-sectional configuration of the solid-state imaging device in the case of being cut along a line I-I′ in FIG. 17.

FIG. 19 is a diagram illustrating a potential distribution in the photoelectric conversion portion.

FIG. 20 is a diagram illustrating a potential distribution in the photoelectric conversion portion.

FIG. 21 is a diagram illustrating potential distributions in regions K, L, M, and N in FIG. 20.

FIG. 22 is a diagram illustrating potential distributions in the regions K, L, M, and N in FIG. 20.

FIG. 23 is a diagram illustrating potential distributions in the regions K, L, M, and N in FIG. 20.

FIG. 24 is a diagram illustrating a cross-sectional configuration of the solid-state imaging device according to a modification.

FIG. 25 is a diagram illustrating a cross-sectional configuration of the solid-state imaging device according to a modification.

FIG. 26 is a diagram illustrating a potential in the case of being viewed from the thickness direction of a semiconductor substrate.

FIG. 27 is a diagram illustrating a potential in the case of being viewed from the thickness direction of a semiconductor substrate.

FIG. 28 is a diagram illustrating a potential in the case of being viewed from the thickness direction of a semiconductor substrate.

FIG. 29 is a diagram illustrating a potential in the case of being viewed from the thickness direction of a semiconductor substrate.

FIG. 30 is a schematic configuration diagram of an electronic device according to a third embodiment.

### MODE FOR CARRYING OUT THE INVENTION

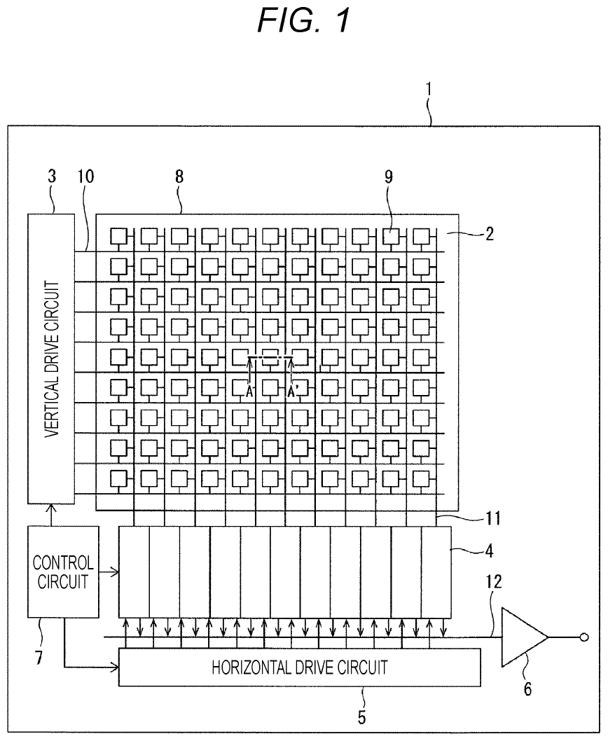

Hereinafter, examples of a photodetection device and an electronic device according to embodiments of the present disclosure will be described with reference to FIGS. 1 to 30. The embodiments of the present disclosure will be described in the following order. Note that, the present disclosure is not limited to the following examples. Furthermore, the effects described in the present specification are illustrative and not restrictive, and there may be additional effects.
1. First Embodiment: Solid-State Imaging Device
1-1 Overall Configuration of Solid-State Imaging Device
1-2 Configuration of Main Part
2. Second Embodiment: Solid-State Imaging Device
2-1 Configuration of Main Part
2-2 Modifications
3. Third Embodiment: Example of Application to Electronic Device

### 1. First Embodiment: Solid-State Imaging Device

### [1-1 Overall Configuration of Solid-State Imaging Device]

A solid-state imaging device 1 (in a broad sense, a “photodetection device”) according to a first embodiment of the present disclosure will be described. FIG. 1 is a diagram illustrating an overall configuration of the solid-state imaging device 1 according to the first embodiment.

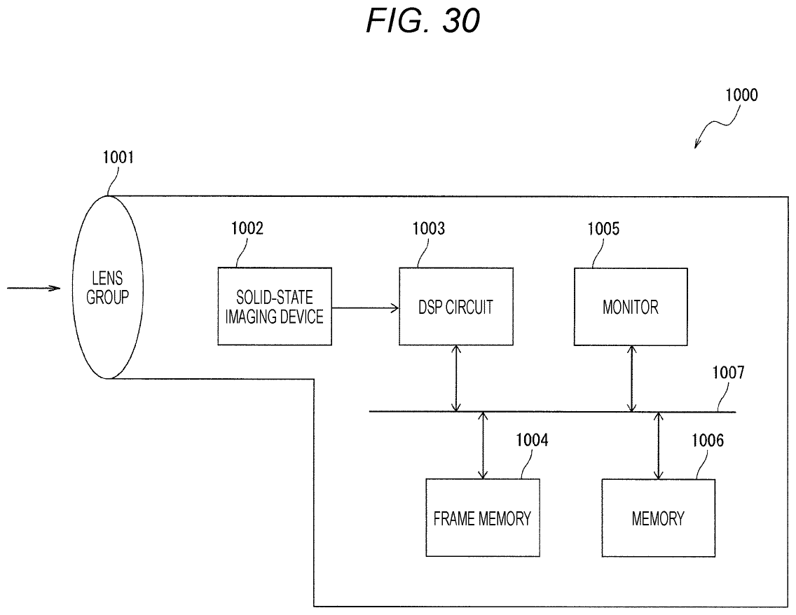

The solid-state imaging device 1 in FIG. 1 is a back-illuminated complementary metal oxide semiconductor (CMOS) image sensor. As illustrated in FIG. 30, the solid-state imaging device 1 (1002) captures image light (incident light) from a subject via a lens group 1001, converts an amount of the incident light forming an image on an imaging surface into an electric signal in units of pixels, and outputs the electric signal as a pixel signal.

As illustrated in FIG. 1, the solid-state imaging device 1 includes a pixel region 2, a vertical drive circuit 3, a column signal processing circuit 4, a horizontal drive circuit 5, an output circuit 6, and a control circuit 7.

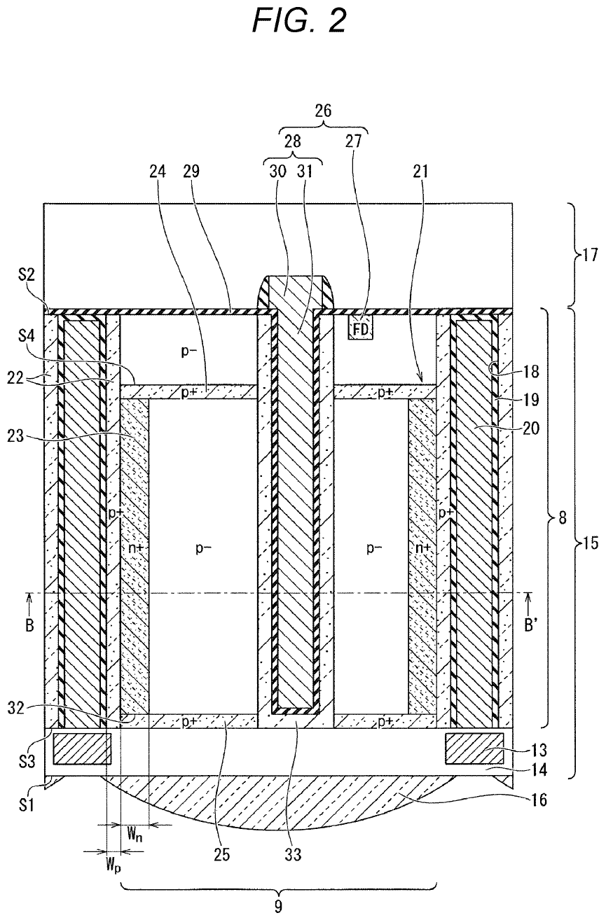

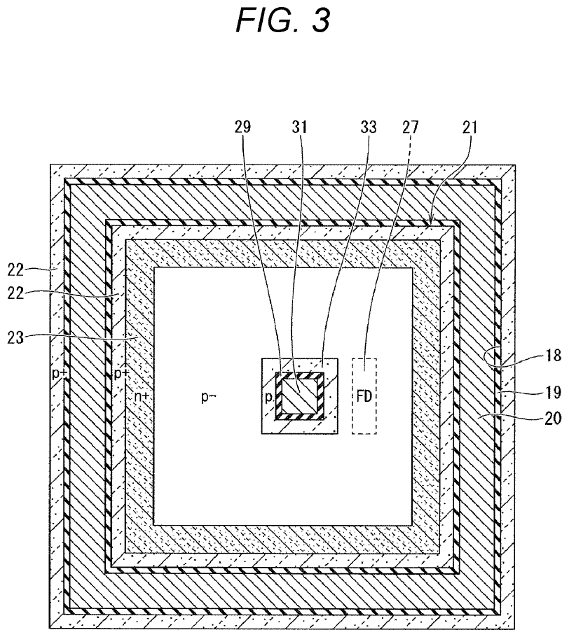

The pixel region 2 includes a plurality of pixels 9 arranged in a two-dimensional array on the semiconductor substrate 8. Each pixel 9 includes a photoelectric conversion portion 21 illustrated in FIGS. 2, and 3, and a plurality of pixel transistors. Examples of the plurality of pixel transistors include a transfer transistor, a reset transistor, an amplification transistor, and a selection transistor.

The vertical drive circuit 3 includes, for example, a shift register, selects a desired pixel drive wiring line 10, supplies a pulse for driving the pixel 9 to the selected pixel drive wiring line 10, and drives the pixels 9 in units of rows. That is, the vertical drive circuit 3 selectively scans the pixels 9 in the pixel region 2 sequentially in a vertical direction in units of rows, and supplies a pixel signal based on a signal charge generated in accordance with an amount of received light in the photoelectric conversion portion 21 of each pixel 9, to the column signal processing circuit 4 through a vertical signal line 11.

The column signal processing circuit 4 is arranged, for example, for each column of the pixels 9, and performs signal processing such as noise removal on signals output from the pixels 9 of one row for each pixel column. For example, the column signal processing circuit 4 performs signal processing such as correlated double sampling (CDS) for removing a fixed pattern noise unique to pixels, and analog-digital (AD) conversion.

The horizontal drive circuit 5 includes, for example, a shift register, sequentially outputs a horizontal scanning pulse to the column signal processing circuit 4, sequentially selects each of the column signal processing circuits 4, and causes each of the column signal processing circuits 4 to output the pixel signal subjected to the signal processing to a horizontal signal line 12.

The output circuit 6 performs signal processing on the pixel signal sequentially supplied from each of the column signal processing circuits 4 through the horizontal signal line 12, and outputs the pixel signal. As the signal processing, for example, buffering, black level adjustment, column variation correction, various types of digital signal processing and the like can be used.

The control circuit 7 generates a clock signal that is a reference for operations and a control signal, for the vertical drive circuit 3, the column signal processing circuits 4, the horizontal drive circuit 5, and the like, on the basis of a vertical synchronization signal, a horizontal synchronization signal, and a master clock signal. Then, the control circuit 7 outputs the generated clock signal and control signal to the vertical drive circuit 3, the column signal processing circuits 4, the horizontal drive circuit 5, and the like.

### [1-2 Configuration of Main Part]

Next, a detailed structure of the solid-state imaging device 1 will be described. FIG. 2 is a diagram illustrating a cross-sectional configuration of the solid-state imaging device 1 in the case of being cut along a line A-A′ in FIG. 1. Furthermore, FIG. 3 is a diagram illustrating a cross-sectional configuration of the solid-state imaging device 1 in the case of being cut along a line B-B′ in FIG. 2.

As illustrated in FIG. 2, in the solid-state imaging device 1, a light-receiving layer 15 is arranged in which a semiconductor substrate 8, a light-shielding film 13, and a planarizing film 14 are stacked in this order. Furthermore, a plurality of microlenses 16 arranged in a two-dimensional array is arranged on a surface (hereinafter, also referred to as a “back surface S1”) on the planarizing film 14 side of the light-receiving layer 15 so as to correspond to the respective pixels 9. Moreover, a wiring layer 17 is arranged on a surface (hereinafter, also referred to as a “front surface S2”) on the semiconductor substrate 8 side of the light-receiving layer 15.

The semiconductor substrate 8 includes, for example, a p-type silicon (Si) substrate. In the semiconductor substrate 8, a trench portion 18 is formed so as to surround a region of each pixel 9. The trench portion 18 is formed to penetrate the semiconductor substrate 8. On an inner wall surface of the trench portion 18, a sidewall film 19 covering the inner wall surface is formed. As a material of the sidewall film 19, for example, a silicon oxide (SiO₂) can be adopted. Furthermore, a filler 20 is embedded inside the trench portion 18. As the filler 20, for example, doped polysilicon can be adopted.

Furthermore, in a region of the semiconductor substrate 8 surrounded by the trench portion 18, the photoelectric conversion portion 21 having a rectangular shape is formed in a region on a light-receiving surface (hereinafter, also referred to as a “back surface S3”) side of the semiconductor substrate 8. In the photoelectric conversion portion 21, as illustrated in FIGS. 2 and 3, a p-type semiconductor region (hereinafter, also referred to as a “p+ region 22”) containing an impurity of p-type with a high concentration and an n-type semiconductor region (hereinafter also referred to as an “n+ region 23”) containing an impurity of n-type with a high-concentration are formed in order from the trench portion 18 side to a central portion side of the photoelectric conversion portion 21. As the impurity of p-type and the impurity of n-type, for example, boron (B) and phosphorus (P) can be adopted. Furthermore, a p-type semiconductor region (hereinafter, also referred to as a “front surface side p+ region 24” and a “back surface side p+ region 25”) containing an impurity of p-type with a high concentration is formed on each of the front surface S2 side and the back surface S3 side of the photoelectric conversion portion 21 so as to suppress a dark current.

The p+ region 22 is formed in a region in contact with the trench portion 18 and is continuously formed in a thickness direction of the semiconductor substrate 8. The p+ region 22 is formed from the front surface S2 side to the back surface S3 side of the semiconductor substrate 8, and has a constant width Wp from the front surface S2 side to the back surface S3 side. Furthermore, the p+ region 22 has a constant impurity concentration in the thickness direction of the semiconductor substrate 8. For example, a difference in concentration of the impurity in each portion in the p+ region 22 is less than or equal to 10%.

Furthermore, the n+ region 23 is formed in a region in contact with the p+ region 22, and is continuously formed in the thickness direction of the semiconductor substrate 8. The n+ region 23 is formed from the front surface side p+ region 24 to the back surface side p+ region 25, and has a constant width Wn from the front surface side p+ region 24 side to the back surface side p+ region 25 side. Furthermore, the n+ region 23 has a constant impurity concentration in the thickness direction of the semiconductor substrate 8 (in other words, it can also be said that the n+ region 23 has a constant resistance value at each portion in the thickness direction of the semiconductor substrate 8). For example, a difference in concentration of the impurity in each portion in the n+ region 23 is less than or equal to 10% (more preferably, less than or equal to 5%). Then, the photoelectric conversion portion 21 constitutes a photodiode by mainly a pn junction that is a junction surface between the p+ region 22 and the n+ region 23, performs photoelectric conversion, and generates a charge according to the amount of received light. Furthermore, the photoelectric conversion portion 21 accumulates the charge generated by the photoelectric conversion in electrostatic capacitance (junction capacitance) generated in the pn junction portion between the p+ region 22 and the n+ region 23.

As a method of forming the p+ region 22 and the n+ region 23, for example, it is possible to adopt a method of forming the trench portion 18 in the semiconductor substrate 8 and then doping impurities into the semiconductor substrate 8 from the inside of the trench portion 18 before forming the sidewall film 19 and the filler 20. Examples of a method for doping impurities include a solid phase diffusion method, plasma doping, and an ion implantation method. Furthermore, as a method of forming the p+ region 22, for example, it is also possible to adopt a method of forming a fixed charge film having a negative charge on the inner wall surface of the trench portion 18. Examples of a material of the fixed charge film include an oxide or nitride containing at least one element of hafnium (Hf), aluminum (Al), zirconium (Zr), tantalum (Ta), or titanium (Ti).

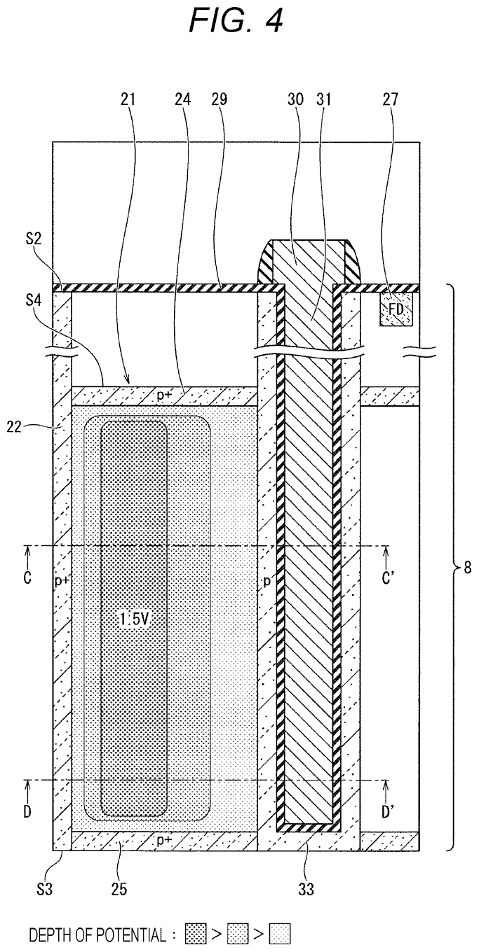

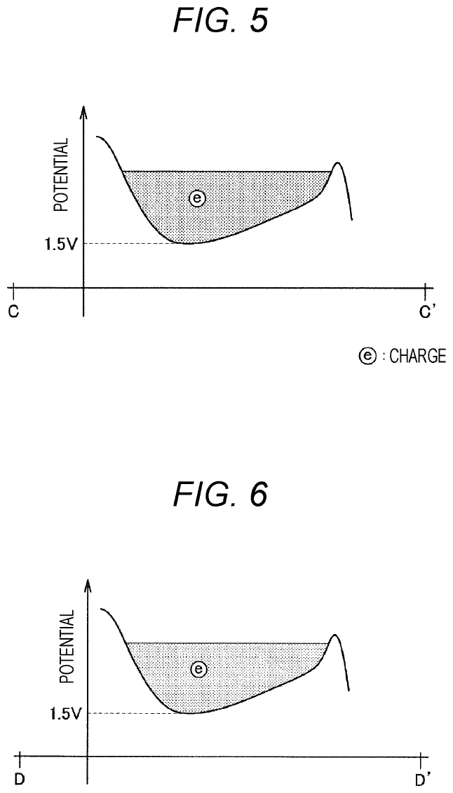

As described above, in the first embodiment, a configuration is employed in which the n+ region 23 of the photoelectric conversion portion 21 is continuous in the thickness direction of the semiconductor substrate 8 so as to be in contact with the p+ region 22, and further, the impurity concentration is constant in the thickness direction of the semiconductor substrate 8. As a result, in the photoelectric conversion portion 21, the same pn junction portion can be formed in each portion in the thickness direction of the semiconductor substrate 8, and as illustrated in FIGS. 4 and 5, a depth of potential on the back surface S3 side of the photoelectric conversion portion 21 can be made about the same as a depth of potential on a front surface S4 side (a root side of a vertical gate electrode 31) as illustrated in FIGS. 4 and 6. In FIGS. 4 to 6, a case is exemplified where a peak of the potential is 1.5 V. For that reason, it is possible to increase an amount of charge (saturated amount of charge Qs) that can be accumulated in the photoelectric conversion portion 21. FIG. 4 is a diagram illustrating a potential distribution in the photoelectric conversion portion 21. Furthermore, FIG. 5 is a diagram illustrating a potential at a position of a line C-C′ in FIG. 4. Furthermore, FIG. 6 is a diagram illustrating a potential at a position of a line D-D′ in FIG. 4.

Furthermore, in the region of the semiconductor substrate 8 surrounded by the trench portions 18, a vertical transistor 26 is formed in a region on the front surface S2 side of the semiconductor substrate 8. The vertical transistor 26 includes a floating diffusion (in a broad sense, a “charge holding portion”. hereinafter, also referred to as “FD 27”) and a transfer gate 28. The FD 27 includes an impurity region of n-type with a high concentration, and holds a charge transferred from the photoelectric conversion portion 21 to the FD 27 by the transfer transistor (transfer gate 28). That is, the charge generated by the photoelectric conversion portion 21 is held.

Furthermore, the transfer gate 28 is a gate of the transfer transistor that transfers the charge generated by the photoelectric conversion portion 21 to the FD 27. The transfer gate 28 is formed in the semiconductor substrate 8 with a gate insulating film 29 interposed therebetween. The transfer gate 28 includes a surface electrode 30 having a flat plate shape formed to protrude from the front surface S2 of the semiconductor substrate 8, and the vertical gate electrode 31 extending from the surface electrode 30 in the thickness direction of the semiconductor substrate 8. The vertical gate electrode 31 extends from the front surface S2 of the semiconductor substrate 8 to a depth deeper than that of an end portion 32 of the n+ region 23 located on the back surface S3 side. That is, the vertical gate electrode 31 extends from the front surface S2 (first surface) that is a surface of two surfaces of the semiconductor substrate 8 and closer to the FD 27 to a depth (depth of the p+ region 25) deeper than that of the end portion 32 of the n+ region 23 located on the back surface S3 (second surface) side that is a surface on a farther side from the front surface S2.

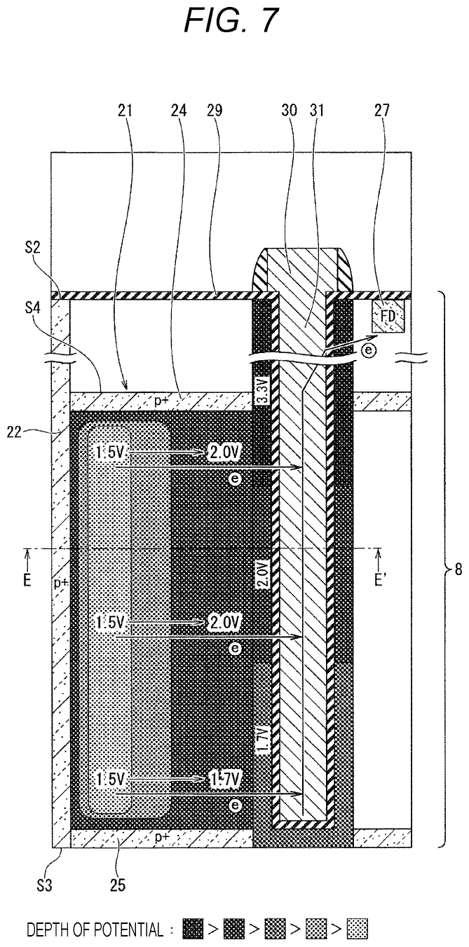

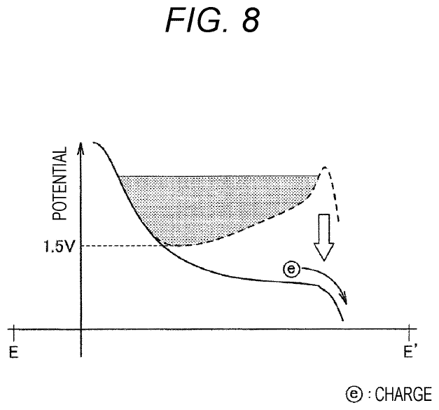

As described above, in the first embodiment, a configuration is employed in which the transfer gate 28 uses the vertical gate electrode 31 extending from the front surface S2 of the semiconductor substrate 8 to the depth deeper than that of the end portion 32 of the n+ region 23 located on the back surface S3 side. As a result, when the charge is transferred to the FD 27, a potential of the vertical gate electrode 31 is set to a HIGH state, so that the potential on the vertical gate electrode 31 side can be deepened in the photoelectric conversion portion 21 as illustrated in FIGS. 7 and 8. In FIG. 7, a case is exemplified where the potential on the vertical gate electrode 31 side is set to 2.0 V or the like. For that reason, it is possible to form a potential gradient that causes horizontal transfer of the charge accumulated in the photoelectric conversion portion 21 to a region on the vertical gate electrode 31 side. FIG. 7 is a diagram illustrating a potential distribution in the photoelectric conversion portion 21. Furthermore, FIG. 8 is a diagram illustrating a potential at a position of a line E-E′ in FIG. 7.

In FIGS. 2 and 3, a case is exemplified where the vertical gate electrode 31 is one buried electrode extending from the front surface S2 of the semiconductor substrate 8 to the depth deeper than that of the end portion of the n+ region 23 located on the back surface S3 side. Furthermore, an impurity region 33 containing an impurity of p-type is formed around the vertical gate electrode 31 (buried electrode 31) so as to cover a peripheral surface of the buried electrode 31. In the impurity region 33, a concentration of the impurity on the back surface S3 side of the semiconductor substrate 8 is higher than a concentration of the impurity on the front surface S2 side. As a result, the potential of the vertical gate electrode 31 is set to the HIGH state, so that the depth of the potential on the front surface S2 side (the root side of the vertical gate electrode 31) of the semiconductor substrate 8 can be made deeper than the depth of the potential on the back surface S3 side, around the buried electrode 31, as illustrated in FIG. 7. For that reason, it is possible to form a potential gradient that causes vertical transfer of the charge horizontally transferred to the buried electrode 31 side to the FD 27, around the buried electrode 31. A configuration may be employed in which the concentration of the impurity in the impurity region 33 changes continuously, or changes stepwise (discontinuously).

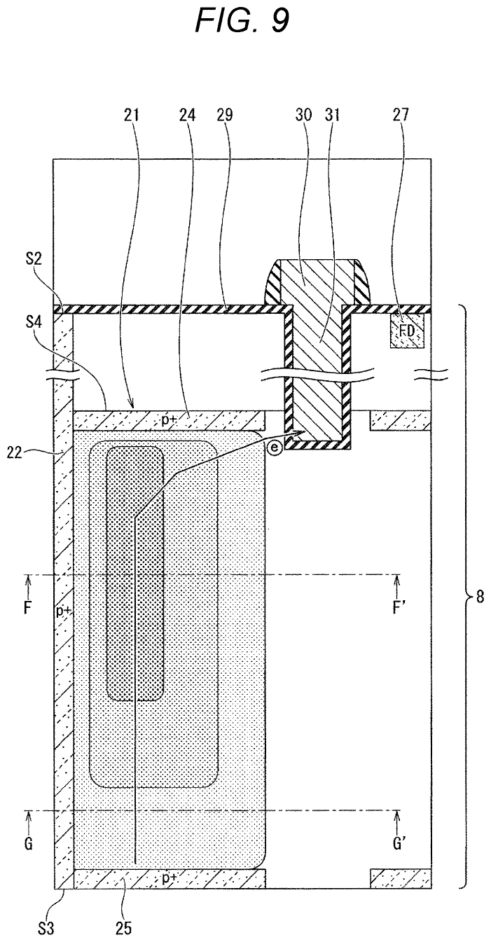

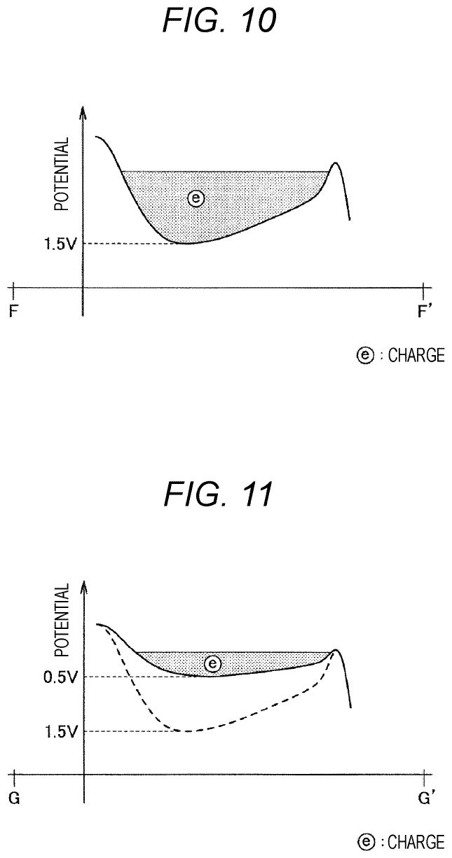

Here, for example, in a case where a configuration is employed in which a potential gradient that causes vertical transfer of the charge to the front surface S2 side of the semiconductor substrate 8 is formed in the photoelectric conversion portion 21 as illustrated in FIG. 9, as illustrated in FIGS. 9 and 10, the depth of the potential on the back surface S3 side becomes shallower than the depth of the potential on the front surface S4 side (the root side of the vertical gate electrode 31) of the photoelectric conversion portion 21 as illustrated in FIGS. 9 and 11. For that reason, there is a possibility that the amount of charge (saturated amount of charge Qs) that can be accumulated as the entire photoelectric conversion portion 21 decreases. FIG. 9 is a diagram illustrating a potential distribution in the photoelectric conversion portion 21. FIG. 10 is a diagram illustrating a potential at a position of a line F-F′ in FIG. 9. FIG. 11 is a diagram illustrating a potential at a position of a line G-G′ in FIG. 9.

On the other hand, in the solid-state imaging device 1 according to the present embodiment, the potential gradient that causes vertical transfer of the charge to the front surface S2 side of the semiconductor substrate 8 is not formed in the photoelectric conversion portion 21, and as illustrated in FIGS. 4, 5, and 6, the depth of the potential on the back surface S3 side of the photoelectric conversion portion 21 is set to be about the same as the depth of the potential on the front surface S4 side (the root side of the vertical gate electrode 31). For that reason, it is possible to increase the amount of charge (saturated amount of charge Qs) that can be accumulated as the entire photoelectric conversion portion 21.

Furthermore, when the charge is transferred to the FD 27, the potential of the vertical gate electrode 31 is set to the HIGH state, so that the potential on the vertical gate electrode 31 side is deepened in the photoelectric conversion portion 21 to form a potential gradient as illustrated in FIGS. 7 and 8. For that reason, the charge accumulated in the photoelectric conversion portion 21 can be horizontally transferred to the region on the vertical gate electrode 31 side.

Furthermore, the potential of the vertical gate electrode 31 is set to the HIGH state, so that the depth of the potential on the front surface S2 side (the root side of the vertical gate electrode 31) of the semiconductor substrate 8 is made deeper than the depth of the potential on the back surface S3 side, around the buried electrode 31, as illustrated in FIG. 7. For that reason, the charge horizontally transferred to the vertical gate electrode 31 (buried electrode 31) side can be vertically transferred to the FD 27 along the vertical gate electrode 31 (buried electrode 31). As a result, the charge generated by the photoelectric conversion portion 21 can be held in the FD 27.

### 2. Second Embodiment: Solid-State Imaging Device

### [2-1 Configuration of Main Part]

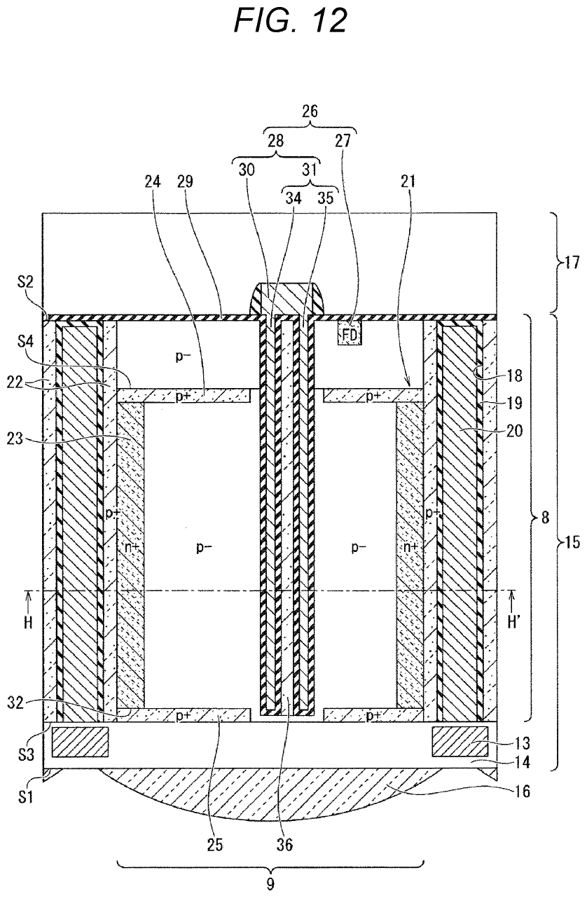

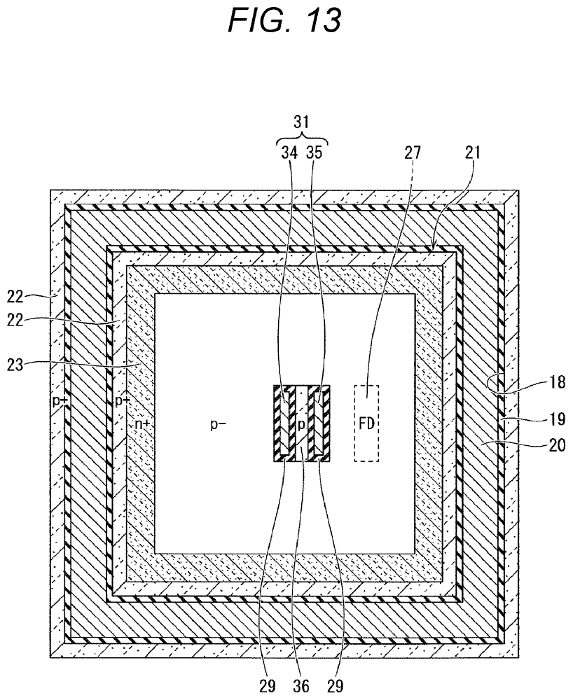

Next, the solid-state imaging device 1 according to a second embodiment of the present disclosure will be described. An overall configuration of the solid-state imaging device 1 according to the second embodiment is similar to that in FIG. 1, and thus illustration thereof will be omitted. FIG. 12 is a diagram illustrating a cross-sectional configuration of the solid-state imaging device 1 according to the second embodiment. FIG. 13 is a diagram illustrating a cross-sectional configuration of the solid-state imaging device 1 in the case of being cut along a line H-H′ in FIG. 12. In FIGS. 12 and 13, portions corresponding to FIGS. 2 and 3 are denoted by the same reference numerals, and redundant description will be omitted.

The second embodiment is different from the first embodiment in that two or more buried electrodes extending from the front surface S2 of the semiconductor substrate 8 in the thickness direction of the semiconductor substrate 8 are used as the vertical gate electrode 31 as illustrated in FIGS. 12 and 13. In FIGS. 12 and 13, a case is exemplified where two buried electrodes 34 and 35 are used as the two or more buried electrodes. The buried electrodes 34 and 35 each are an electrode having the same prismatic shape arranged apart from each other in a direction orthogonal to the thickness direction of the semiconductor substrate 8. Each of the buried electrodes 34 and 35 extends to a depth deeper than that of the end portion 32 of the n+ region 23 located on the back surface S3 side of the semiconductor substrate 8.

Furthermore, an impurity region 36 containing an impurity of p-type is formed between the buried electrodes 34 and 35. In the impurity region 36, a concentration of the impurity on the front surface S2 side of the semiconductor substrate 8 is higher than a concentration of the impurity on the back surface S3 side. A configuration may be employed in which the concentration of the impurity in the impurity region 36 changes continuously, or changes stepwise (discontinuously).

Here, in the solid-state imaging device 1 illustrated in FIG. 2 of the first embodiment, the impurity region 33 for forming the potential gradient for vertical transfer of the charge is formed so as to cover the peripheral surface of the vertical gate electrode 31. For that reason, there is a possibility that the impurity forming the impurity region 33 affects the photoelectric conversion portion 21 and the potential of the photoelectric conversion portion 21 fluctuates. In a region on the back surface S3 side of the photoelectric conversion portion 21, a potential of a region near the vertical gate electrode 31 does not become deeper than or equal to a potential of a region on the back surface S3 side of the impurity region 33. For that reason, as illustrated in FIG. 7, in the region on the back surface S3 side of the photoelectric conversion portion 21, the potential of the region near the vertical gate electrode 31 becomes shallow (in FIG. 7, 1.7 V), and there is a possibility that the amount of charge that can be accumulated is reduced.

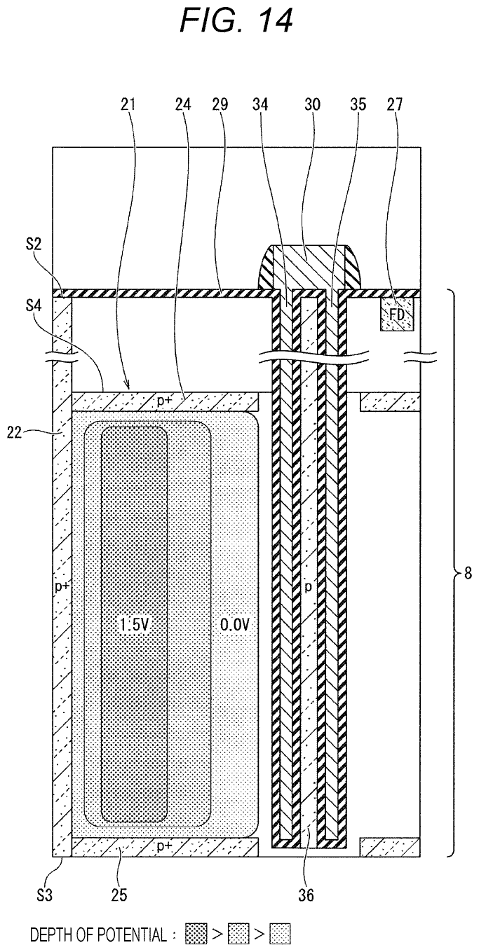

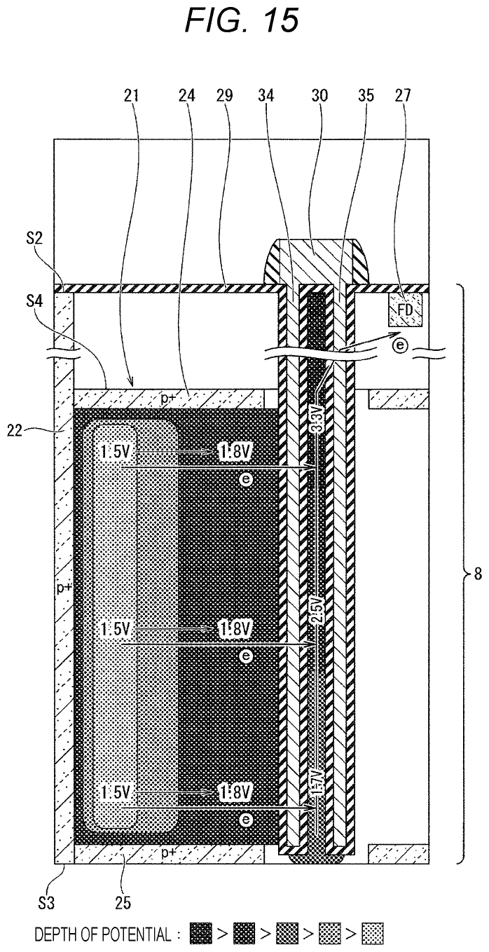

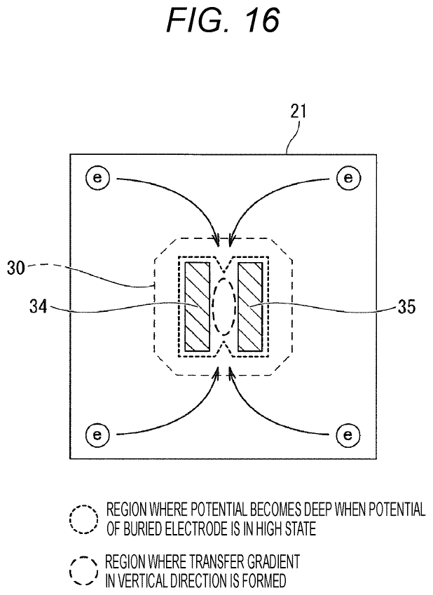

On the other hand, in the solid-state imaging device 1 according to the second embodiment, the impurity region for forming the potential gradient for vertical transfer of the charge is not formed around the vertical gate electrode 31, and the impurity region 36 is formed between the buried electrodes 34 and 35 constituting the vertical gate electrode 31 as illustrated in FIGS. 12, 13, and 14. As a result, when the charge is transferred to the FD 27, potentials of the buried electrodes 34 and 35 are set to the HIGH state, so that the depth of the potential on the front surface S2 side (the root side of the vertical gate electrode 31) of the semiconductor substrate 8 can be made deeper than the depth of the potential on the back surface S3 side, between the buried electrodes 34 and 35, as illustrated in FIG. 15. For that reason, as illustrated in FIG. 16, it is possible to form a potential gradient that causes vertical transfer of the charge horizontally transferred to the buried electrodes 34 and 35 sides to the FD 27. Furthermore, it is possible to suppress fluctuation of the potential of the photoelectric conversion portion 21 due to the impurity in the impurity region 36. In FIG. 15, potentials of respective portions in regions on the buried electrodes 34 and 35 sides in the photoelectric conversion portion 21 are the same (1.8 V). For that reason, it is possible to suppress reduction in the amount of charge that can be accumulated in the photoelectric conversion portion 21, and it is possible to suppress reduction in the saturated amount of charge Qs. FIGS. 14 and 15 are diagrams illustrating a potential distribution in the photoelectric conversion portion 21, FIG. 14 is a potential distribution in a case where the potentials of the buried electrodes 34 and 35 are in a LOW state, and FIG. 15 is a potential distribution in a case where the potentials are in the HIGH state. FIG. 16 is a diagram illustrating a potential in the case of being viewed from the thickness direction of the semiconductor substrate 8. In FIG. 16, the buried electrodes 34 and 35 are drawn larger than those in other figures.

### [2-2 Modifications]

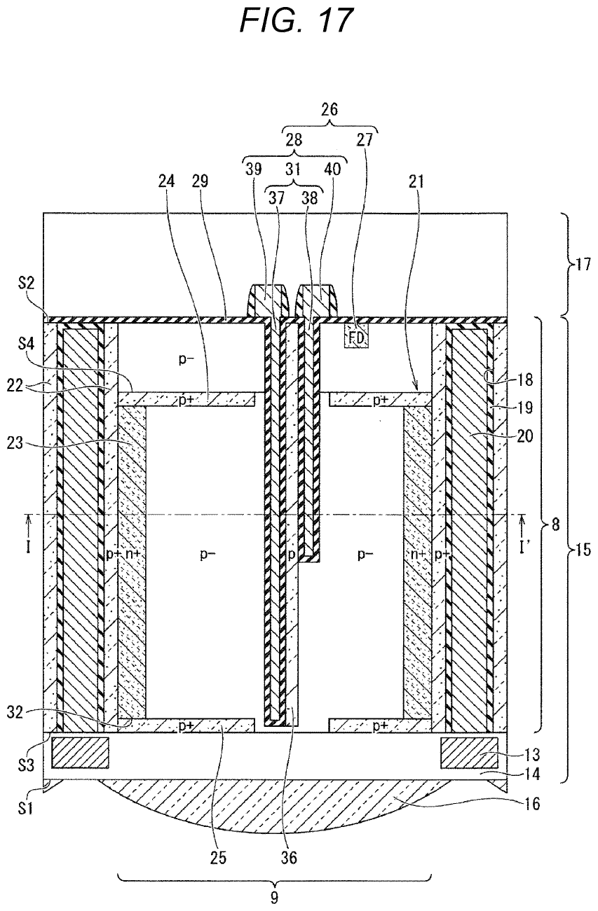

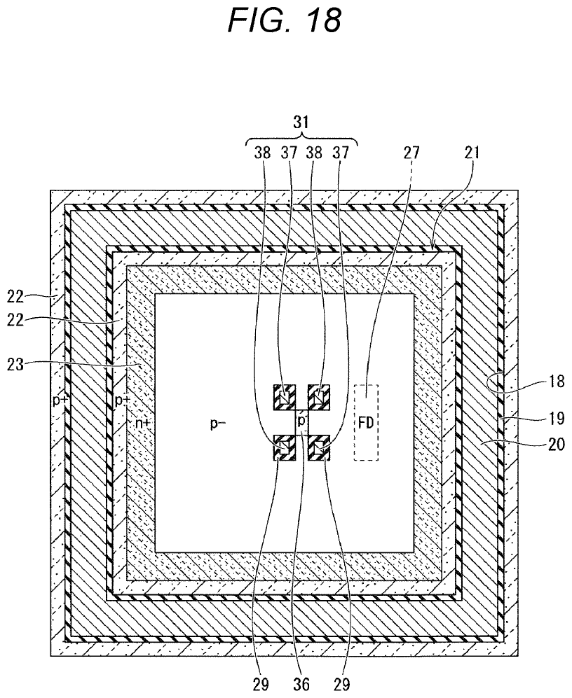

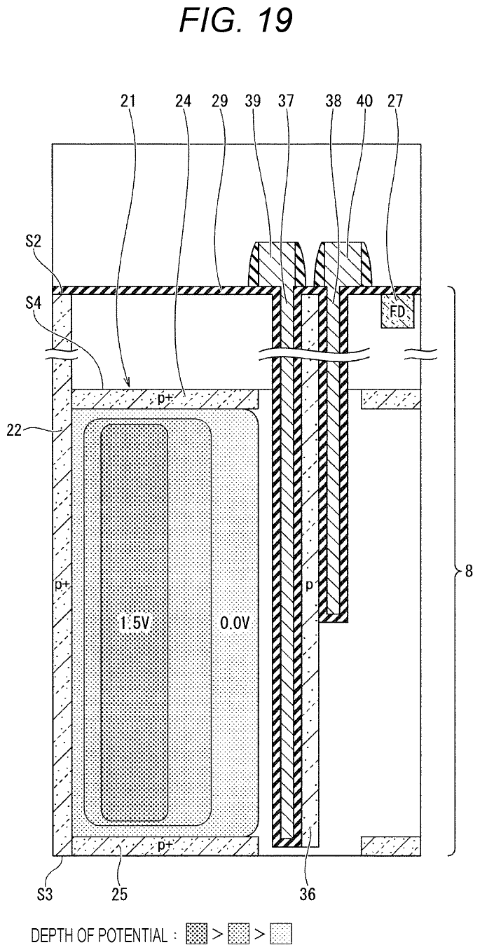

(1) Note that, in the second embodiment, as illustrated in FIG. 12, an example has been described in which two or more buried electrodes 34 and 35 have the same prismatic shape (the same length and a constant separation distance), but other configurations can be adopted. For example, a configuration may be employed in which the two or more buried electrodes 34 and 35 illustrated in FIG. 12 include at least a first electrode 37 extending from the front surface S2 of the semiconductor substrate 8 to a depth deeper than that of the end portion 32 of the n+ region 23 located on the back surface S3 side and a second electrode 38 extending from the front surface S2 of the semiconductor substrate 8 to a depth shallower than that of the first electrode 37, as illustrated in FIGS. 17 and 18. Here, in FIGS. 17 and 18, a case is exemplified where two first electrodes 37 and two second electrodes 38 are provided, the electrodes are arranged in a 2×2 matrix, the first electrodes 37 are located on one diagonal line of the matrix, and the second electrodes 38 are located on the other diagonal line. FIG. 18 is a diagram illustrating a cross-sectional configuration of the solid-state imaging device 1 in the case of being cut along a line I-I′ in FIG. 17. Furthermore, the potential distribution in the photoelectric conversion portion 21 is a distribution as illustrated in FIG. 19.

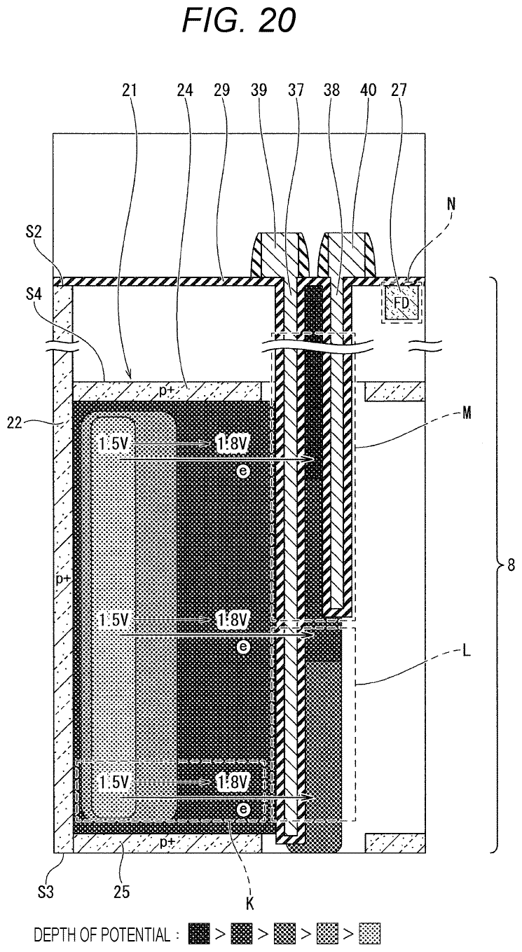

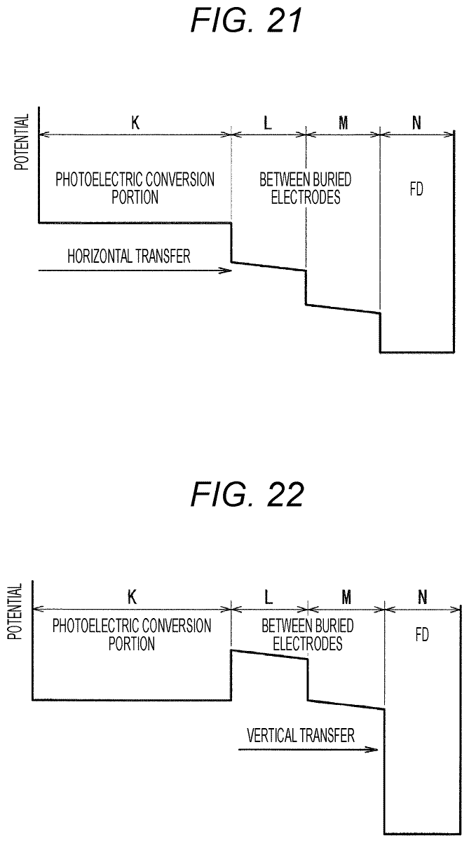

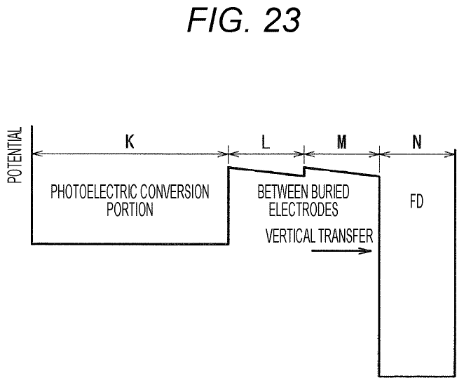

Furthermore, in FIG. 17, the surface electrode 30 illustrated in FIG. 12 is replaced with surface electrodes 39 and 40 individually formed at the end portion on the front surface S2 side of each of the first electrode 37 and the second electrode 38, and formed so as to protrude from the front surface S2 of the semiconductor substrate 8. As a result, potentials of the first electrode 37 and the second electrode 38 can be individually controlled via the surface electrodes 39 and 40. When the charge is transferred to the FD 27, first, potentials of the surface electrodes 39 and 40 are set to the HIGH state, so that the potentials of both the first electrode 37 and the second electrode 38 are set to the HIGH state. Then, as illustrated in FIGS. 20 and 21, in the photoelectric conversion portion 21, potentials on the first electrode 37 side and the second electrode 38 side become deep, a potential gradient that causes horizontal transfer of the charge to the first electrode 37 side and the second electrode 38 side is formed, and the charge accumulated in the photoelectric conversion portion 21 (a region K in FIG. 20) is transferred between the first electrodes 37 and between the second electrodes 38 (regions L and M in FIG. 20). As a result, the charge is accumulated in each portion in the thickness direction of the semiconductor substrate 8 between the first electrodes 37 and between the second electrodes 38. FIG. 21 is a diagram illustrating potential distributions in regions K, L, M, and N in FIG. 20. Subsequently, only the potential of the surface electrode 39 is set to the LOW state, so that only the potential of the first electrode 37 is set to the LOW state, and the potential of the second electrode 38 is maintained at HIGH. Then, as illustrated in FIG. 22, a potential on the back surface S3 side of the semiconductor substrate 8 becomes shallow between the first electrodes 37 and between the second electrodes 38, and the charge on the back surface S3 side (the region L side in FIG. 20) is vertically transferred to the front surface S2 side (the region M side in FIG. 20). As a result, the charge is accumulated in a region on the front surface S2 side (the region M side in FIG. 20) between the first electrodes 37 and between the second electrodes 38. Subsequently, the potential of the surface electrode 40 is also set to the LOW state, so that the potentials of both the first electrode 37 and the second electrode 38 are set to the LOW state. Then, as illustrated in FIG. 23, the charge on the front surface S2 side (the region M side in FIG. 20) is transferred to the FD 27 (the region N in FIG. 20). As a result, vertical transfer of the charge can be efficiently performed.

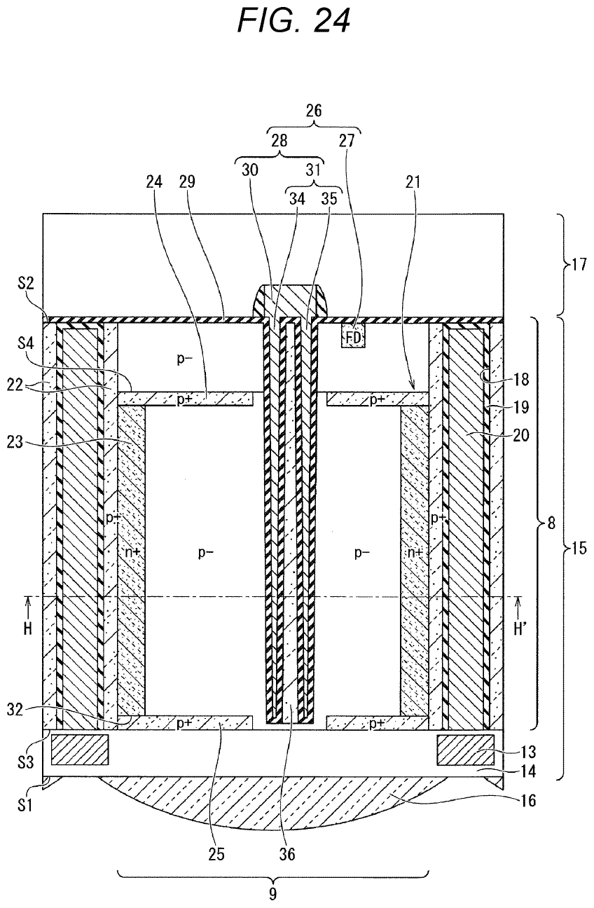

(2) Furthermore, for example, as illustrated in FIG. 24, a configuration may be employed in which a distance between the buried electrodes 34 and 35 on the back surface S3 side of the semiconductor substrate 8 is made larger than a distance between the buried electrodes 34 and 35 on the front surface S2 side. For example, a shape of the buried electrodes 34 and 35 is made to be a truncated cone shape obtained by cutting off an upper portion of a cone. Here, the potential between the buried electrodes 34 and 35 becomes deeper as the distance between the buried electrodes 34 and 35 decreases, and becomes shallower as the distance increases. For that reason, according to the configuration illustrated in FIG. 24, a potential gradient for vertical transfer of the charge can be formed such that the potential becomes deeper as the position approaches to the front surface S2 side from the back surface S3 side of the semiconductor substrate 8.

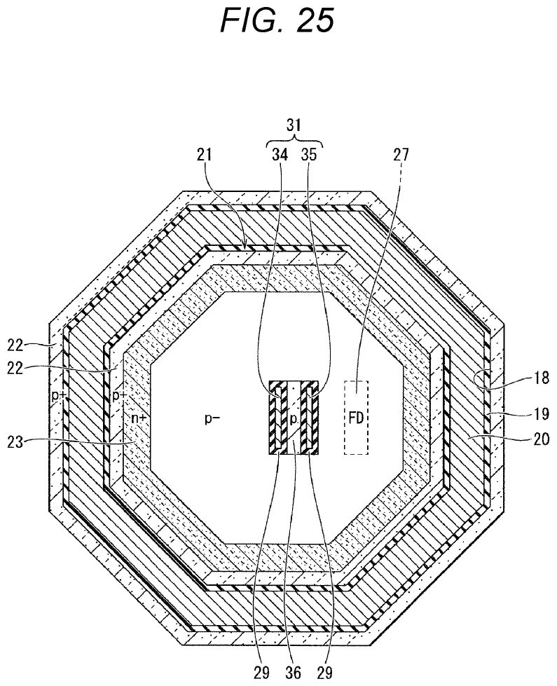

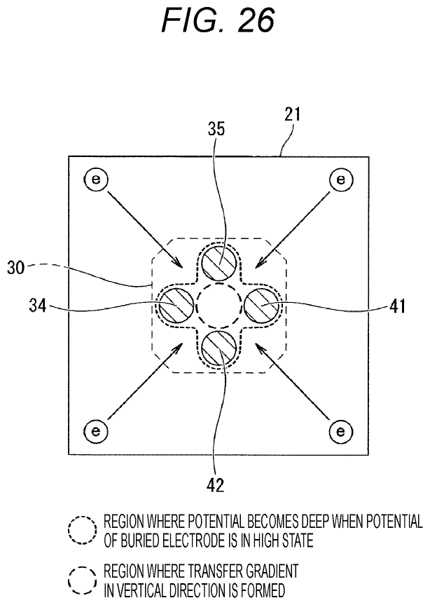

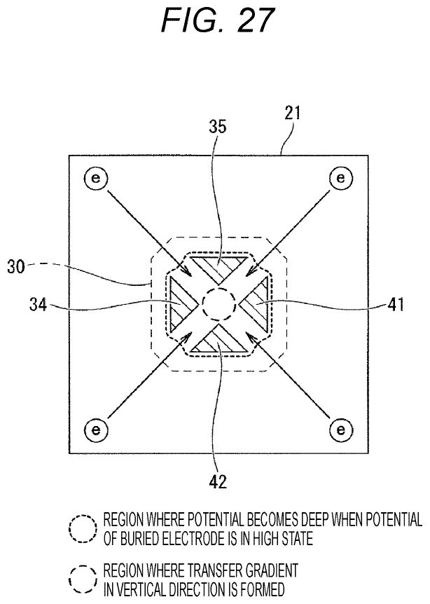

(3) Furthermore, in the second embodiment, an example has been described in which the shape of the outer periphery of the photoelectric conversion portion 21 is rectangular, and the two or more buried electrodes 34 and 35 are prismatic, but other configurations can be adopted. For example, as illustrated in FIG. 25, a configuration may be employed in which the shape of the outer periphery of the photoelectric conversion portion 21 is an n-polygon (n is an integer greater than or equal to four) in the case of being viewed from the thickness direction of the semiconductor substrate 8. Examples of the shape include a rectangle and an octagon. In FIG. 25, a case is exemplified where the shape of the outer periphery of the photoelectric conversion portion 21 is an octagon. Furthermore, as illustrated in FIGS. 26 and 27, a configuration may be employed in which each of two or more buried electrodes 34, 35, 41, and 42 is arranged at a position not overlapping a straight line extending from a corner portion of an n-polygon to a central portion of the photoelectric conversion portion 21 in the case of being viewed from the thickness direction of the semiconductor substrate 8. As a result, it is possible to linearly horizontally transfer the charge accumulated near the corner portion of the photoelectric conversion portion 21 having the n-polygonal shape to regions between the buried electrodes 34, 35, 41, and 42, and perform horizontal transfer of the charge more efficiently. Note that, in FIGS. 26 and 27, a case is exemplified where the shape of the outer periphery of the photoelectric conversion portion 21 is rectangular, but the shape may be another n-polygon (n is an integer greater than or equal to four) such as an octagon.

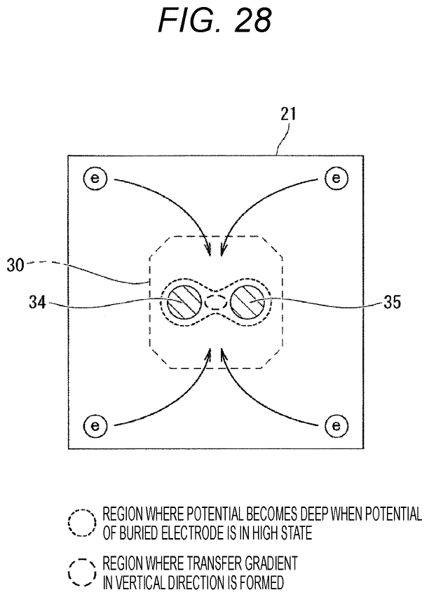

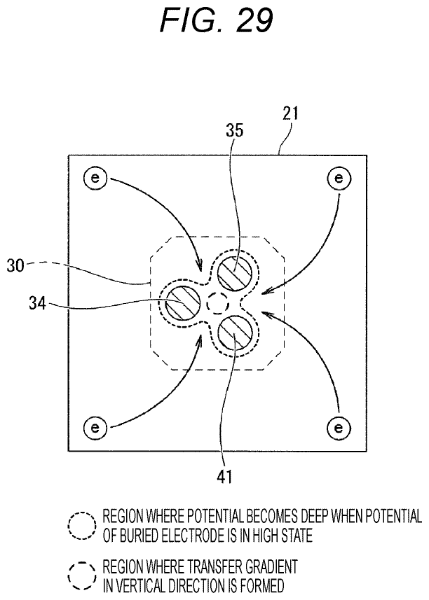

In the case of the configurations illustrated in FIGS. 26 and 27, for example, a circular shape, a rectangular shape, or a triangular shape can be adopted as a cross-sectional shape of the two or more buried electrodes 34, 35, 41, and 42 in a cross section orthogonal to the thickness direction of the semiconductor substrate 8. Note that, as illustrated in FIGS. 28 and 29, also in the case of a configuration in which any of the two or more buried electrodes 34, 35, 41, and 42 is arranged at a position overlapping the straight line extending from the corner portion of the n-polygon (n is an integer greater than or equal to four) to the central portion of the photoelectric conversion portion 21, a circular shape, a rectangular shape, or a triangular shape can be adopted as a cross-sectional shape of the buried electrodes 34 and 35.

(4) Furthermore, the present technology can be applied to all photodetection devices including a distance measuring sensor or the like that measures a distance, also referred to as a time of flight (ToF) sensor, in addition to the solid-state imaging device 1 as the image sensor described above. The distance measuring sensor is a sensor that emits irradiation light toward an object, detects reflected light that is the irradiation light reflected by a surface of the object, and calculates a distance to the object on the basis of a flight time from emission of the irradiation light to reception of the reflected light. As a light-receiving pixel structure of the distance measuring sensor, the structure of the pixel 9 described above can be adopted.

### 3. Third Embodiment: Solid-State Imaging Device

The technology (present technology) according to the present disclosure may be applied to various electronic devices.

FIG. 30 is a diagram illustrating an example of a schematic configuration of an imaging device (video camera, digital still camera, or the like) as an electronic device to which the present technology is applied.

As illustrated in FIG. 30, an imaging device 1000 includes the lens group 1001, the solid-state imaging device 1002 (the solid-state imaging device 1 according to the first embodiment), a digital signal processor (DSP) circuit 1003, a frame memory 1004, a monitor 1005, and a memory 1006. The DSP circuit 1003, the frame memory 1004, the monitor 1005, and the memory 1006 are connected to each other via a bus line 1007.

The lens group 1001 guides incident light (image light) from a subject to the solid-state imaging device 1002 to form an image on a light-receiving surface (pixel region) of the solid-state imaging device 1002.

The solid-state imaging device 1002 includes the CMOS image sensor of the first embodiment described above. The solid-state imaging device 1002 converts an amount of incident light forming an image on the light-receiving surface by the lens group 1001 into an electrical signal in units of pixels and supplies the electrical signal to the DSP circuit 1003 as a pixel signal.

The DSP circuit 1003 performs predetermined image processing on the pixel signal supplied from the solid-state imaging device 1002. Then, the DSP circuit 1003 supplies an image signal subjected to the image processing to the frame memory 1004 in units of frames to temporarily store the image signal in the frame memory 1004.

The monitor 1005 includes, for example, a panel type display device such as a liquid crystal panel or an organic electro luminescence (EL) panel. The monitor 1005 displays the image (moving image) of the subject on the basis of the pixel signal for each frame temporarily stored in the frame memory 1004.

The memory 1006 includes a DVD, a flash memory, or the like. The memory 1006 reads and records the pixel signal for each frame temporarily stored in the frame memory 1004.

Note that the electronic device to which the solid-state imaging device 1 can be applied is not limited to the imaging device 1000, and the solid-state imaging device 1 can also be applied to other electronic devices. Furthermore, the solid-state imaging device 1 according to the first embodiment is used as the solid-state imaging device 1002, but other configurations can also be adopted. For example, a configuration may be employed in which another photodetection device to which the present technology is applied is used, such as the solid-state imaging device 1 according to the second embodiment or the solid-state imaging device 1 according to the modifications.

Note that, the present technology can also have the following configurations.

(1)

A photodetection device including:
a semiconductor substrate;
a photoelectric conversion portion that is formed on the semiconductor substrate and generates and accumulates a charge according to an amount of received light;
a charge holding portion that holds the charge generated by the photoelectric conversion portion; and
a transfer gate that transfers the charge accumulated by the photoelectric conversion portion to the charge holding portion, in which
the photoelectric conversion portion includes a p-type semiconductor region containing an impurity of p-type and formed continuously in a thickness direction of the semiconductor substrate, and an n-type semiconductor region containing an impurity of n-type and formed in a region in contact with the p-type semiconductor region and formed continuously in the thickness direction of the semiconductor substrate,
the n-type semiconductor region has a constant impurity concentration in the thickness direction of the semiconductor substrate, and
the transfer gate includes a vertical gate electrode extending from a first surface that is a surface of two surfaces of the semiconductor substrate and closer to the charge holding portion to a depth deeper than that of an end portion of the n-type semiconductor region located on a side of a second surface that is a surface on an opposite side from the first surface.
   (2)

The photodetection device according to (1), in which
the vertical gate electrode is two or more buried electrodes extending from the first surface of the semiconductor substrate in the thickness direction of the semiconductor substrate.
   (3)

The photodetection device according to (2), further including
an impurity region including an impurity of p-type formed between the two or more buried electrodes, in which
in the impurity region, a concentration of the impurity on a side of the first surface of the semiconductor substrate is higher than a concentration of the impurity on the side of the second surface.
   (4)

The photodetection device according to (2), in which
the two or more buried electrodes at least include a first electrode extending from the first surface of the semiconductor substrate to a depth deeper than that of the end portion of the n-type semiconductor region, and a second electrode extending from the first surface of the semiconductor substrate to a depth shallower than that of the first electrode, and
include a plurality of surface electrodes individually formed at respective end portions of the first electrode and the second electrode on a side of the first surface and formed to protrude from a front surface of the semiconductor substrate.
   (5)

The photodetection device according to (2), in which
a shape of an outer periphery of the photoelectric conversion portion is an n-polygon in a case of being viewed from the thickness direction of the semiconductor substrate, where n is an integer greater than or equal to four, and
each of the two or more buried electrodes is arranged at a position not overlapping a straight line extending from a corner portion of the n-polygon to a central portion of the photoelectric conversion portion in the case of being viewed from the thickness direction of the semiconductor substrate.
   (6)

The photodetection device according to (1), in which
the vertical gate electrode is one buried electrode extending from the first surface of the semiconductor substrate to a depth deeper than that of the end portion of the n-type semiconductor region,
an impurity region including an impurity of p-type formed to cover a peripheral surface of the buried electrode is included, and
in the impurity region, a concentration of the impurity on a side of the first surface of the semiconductor substrate is higher than a concentration of the impurity on the side of the second surface.
   (7)

An electronic device including
a photodetection device including: a semiconductor substrate; a photoelectric conversion portion that is formed on the semiconductor substrate and generates and accumulates a charge according to an amount of received light; a charge holding portion that holds the charge generated by the photoelectric conversion portion; and a transfer gate that transfers the charge accumulated by the photoelectric conversion portion to the charge holding portion, in which the photoelectric conversion portion includes a p-type semiconductor region containing an impurity of p-type and formed continuously in a thickness direction of the semiconductor substrate, and an n-type semiconductor region containing an impurity of n-type and formed in a region in contact with the p-type semiconductor region and formed continuously in the thickness direction of the semiconductor substrate, the n-type semiconductor region has a constant impurity concentration in the thickness direction of the semiconductor substrate, and the transfer gate includes a vertical gate electrode extending from a first surface that is a surface of two surfaces of the semiconductor substrate and closer to the charge holding portion to a depth deeper than that of an end portion of the n-type semiconductor region located on a side of a second surface that is a surface on an opposite side from the first surface.

### REFERENCE SIGNS LIST

1 Solid-state imaging device
2 Pixel region
3 Vertical drive circuit
4 Column signal processing circuit
5 Horizontal drive circuit
6 Output circuit
7 Control circuit
8 Semiconductor substrate
9 Pixel
10 Pixel drive wiring line
11 Vertical signal line
12 Horizontal signal line
13 Light-shielding film
14 Planarizing film
15 Light-receiving layer
16 Microlens
17 Wiring layer
18 Trench portion
19 Sidewall film
20 Filler
21 Photoelectric conversion portion
22 p+ region
23 n+ region
24 Front surface side p+ region
25 Back surface side p+ region
26 Vertical transistor
27 FD
28 Transfer gate
29 Gate insulating film
30 Surface electrode
31 Vertical gate electrode, buried electrode
32 End portion
33 Impurity region
34, 35 Buried electrode
36 Impurity region
37 First electrode
38 Second electrode
39, 40 Surface electrode
1000 Imaging device
1001 Lens group
1002 Solid-state imaging device
1003 DSP circuit
1004 Frame memory
1005 Monitor
1006 Memory
1007 Bus line

1. A photodetection device comprising:
a semiconductor substrate;
a photoelectric conversion portion that is formed on the semiconductor substrate and generates and accumulates a charge according to an amount of received light;
a charge holding portion that holds the charge generated by the photoelectric conversion portion; and
a transfer gate that transfers the charge accumulated by the photoelectric conversion portion to the charge holding portion, wherein
the photoelectric conversion portion includes a p-type semiconductor region containing an impurity of p-type and formed continuously in a thickness direction of the semiconductor substrate, and an n-type semiconductor region containing an impurity of n-type and formed in a region in contact with the p-type semiconductor region and formed continuously in the thickness direction of the semiconductor substrate,
the n-type semiconductor region has a constant impurity concentration in the thickness direction of the semiconductor substrate, and
the transfer gate includes a vertical gate electrode extending from a first surface that is a surface of two surfaces of the semiconductor substrate and closer to the charge holding portion to a depth deeper than that of an end portion of the n-type semiconductor region located on a side of a second surface that is a surface on an opposite side from the first surface.

2. The photodetection device according to claim 1, wherein
the vertical gate electrode is two or more buried electrodes extending from the first surface of the semiconductor substrate in the thickness direction of the semiconductor substrate.

3. The photodetection device according to claim 2, further comprising
an impurity region including an impurity of p-type formed between the two or more buried electrodes, wherein
in the impurity region, a concentration of the impurity on a side of the first surface of the semiconductor substrate is higher than a concentration of the impurity on the side of the second surface.

4. The photodetection device according to claim 2, wherein
the two or more buried electrodes at least include a first electrode extending from the first surface of the semiconductor substrate to a depth deeper than that of the end portion of the n-type semiconductor region, and a second electrode extending from the first surface of the semiconductor substrate to a depth shallower than that of the first electrode, and
include a plurality of surface electrodes individually formed at respective end portions of the first electrode and the second electrode on a side of the first surface and formed to protrude from a front surface of the semiconductor substrate.

5. The photodetection device according to claim 2, wherein
a shape of an outer periphery of the photoelectric conversion portion is an n-polygon in a case of being viewed from the thickness direction of the semiconductor substrate, where n is an integer greater than or equal to four, and
each of the two or more buried electrodes is arranged at a position not overlapping a straight line extending from a corner portion of the n-polygon to a central portion of the photoelectric conversion portion in the case of being viewed from the thickness direction of the semiconductor substrate.

6. The photodetection device according to claim 1, wherein
the vertical gate electrode is one buried electrode extending from the first surface of the semiconductor substrate to a depth deeper than that of the end portion of the n-type semiconductor region,
an impurity region including an impurity of p-type formed to cover a peripheral surface of the buried electrode is included, and
in the impurity region, a concentration of the impurity on a side of the first surface of the semiconductor substrate is higher than a concentration of the impurity on the side of the second surface.

7. An electronic device comprising
a photodetection device including: a semiconductor substrate; a photoelectric conversion portion that is formed on the semiconductor substrate and generates and accumulates a charge according to an amount of received light; a charge holding portion that holds the charge generated by the photoelectric conversion portion; and a transfer gate that transfers the charge accumulated by the photoelectric conversion portion to the charge holding portion, wherein the photoelectric conversion portion includes a p-type semiconductor region containing an impurity of p-type and formed continuously in a thickness direction of the semiconductor substrate, and an n-type semiconductor region containing an impurity of n-type and formed in a region in contact with the p-type semiconductor region and formed continuously in the thickness direction of the semiconductor substrate, the n-type semiconductor region has a constant impurity concentration in the thickness direction of the semiconductor substrate, and the transfer gate includes a vertical gate electrode extending from a first surface that is a surface of two surfaces of the semiconductor substrate and closer to the charge holding portion to a depth deeper than that of an end portion of the n-type semiconductor region located on a side of a second surface that is a surface on an opposite side from the first surface.
